(19) United States
(12) Patent Application Publication
(10) Pub. No.: US 2013/0313521 A1
(43) Pub. Date: Nov. 28, 2013

(54) PHOTODIODE AND METHOD FOR PRODUCING THE SAME

(71) Applicants: Katsushi Akita, Itami-shi (JP); Takashi Ishizuka, Itami-shi (JP); Kei Fujii, Itami-shi (JP); Youichi Nagai, Osaka-shi (JP); Hiroshi Inada, Osaka-shi (JP); Yasuhiro Iguchi, Osaka-shi (JP)

(72) Inventors: Katsushi Akita, Itami-shi (JP); Takashi Ishizuka, Itami-shi (JP); Kei Fujii, Itami-shi (JP); Youichi Nagai, Osaka-shi (JP); Hiroshi Inada, Osaka-shi (JP); Yasuhiro Iguchi, Osaka-shi (JP)

(73) Assignee: Sumitomo Electric Industries, Ltd., Osaka-shi, Osaka (JP)

(21) Appl. No.: 14/000,187

(22) PCT Filed: Feb. 3, 2012
(86) PCT No.: PCT/JP2012/052478

§ 371 Date: Aug. 16, 2013

(30) Foreign Application Priority Data
Feb. 23, 2011 (JP) 2011-037182

(51) Int. Cl. H01L 31/0352

(52) U.S. Cl. CPC H01L 31/035209
USPC 257/21; 438/94

(57) ABSTRACT

An object of the present invention is to provide, for example, a photodiode that can have sufficiently high sensitivity in a near-infrared wavelength range of 1.5 μm to 1.8 μm and can have a low dark current. A photodiode (10) according to the present invention includes a buffer layer (2) positioned on and in contact with an InP substrate (1), and an absorption layer (3) positioned on and in contact with the buffer layer, wherein the absorption layer includes 50 or more pairs in which a first semiconductor layer 3a and a second semiconductor layer 3b constitute a single pair, the first semiconductor layer 3a having a bandgap energy of 0.73 eV or less, the second semiconductor layer 3b having a larger bandgap energy than the first semiconductor layer 3a, and the first semiconductor layer 3a and the second semiconductor layer 3b constitute a strain-compensated quantum well structure and each have a thickness of 1 nm or more and 10 nm or less.

### TECHNICAL FIELD

The present invention relates to a photodiode and a method for producing the photodiode. Specifically, the present invention relates to a photodiode including an absorption layer having a multiple-quantum well structure (hereafter, referred to as MQW) in which sensitivity in a near-infrared wavelength range of 1.5 μm to 1.8 μm is ensured; and a method for producing the photodiode.

### BACKGROUND ART

InP-based semiconductors, which are III-V compound semiconductors, have a bandgap energy corresponding to the near-infrared range and hence a large number of studies are performed for developing photodiodes for communications, image capturing at night, and the like.

For example, Non Patent Literature 1 proposes a photodiode in which an InGaAs/GaAsSb type-II MQW is formed on an InP substrate and a p-n junction is formed with a p-type or n-type epitaxial layer to achieve a cutoff wavelength of 2.39 μm, the photodiode having characteristic sensitivity in a wavelength range of 1.7 μm to 2.7 μm.

In addition, Non Patent Literature 2 describes a photodiode having a type-II MQW absorption layer having 150 pairs layered such that 5 nm InGaAs and 5 nm GaAsSb constitute a single pair, the photodiode having characteristic sensitivity (200 K, 250 K, and 295 K) in a wavelength range of 1 μm to 3 μm.

Furthermore, Patent Literature 1 proposes a photodiode having an InP substrate and an absorption layer that is formed on the InP substrate and includes In_{0.53}Ga_{0.47}As (first absorbing layer) having the composition providing a smaller lattice constant than the InP substrate and In_{0.55}Ga_{0.45}As (second absorbing layer) having the composition providing a larger lattice constant than the InP substrate, for the purpose of slightly increasing the upper-limit wavelength of the absorption range for optical communications. Patent Literature 1 states that the absorption range can be widened to a long wavelength of about 1700 nm.

### CITATION LIST

### Non Patent Literature

NPL 1: R. Sidhu, et. al. “A Long-Wavelength Photodiode on InP Using Lattice-Matched GaInAs—GaAsSb Type-II Quantum Wells, IEEE Photonics Technology Letters, Vol. 17, No. 12 (2005), pp. 2715-2717
NPL 2: R. Sidhu, et. al. “A 2.3 μm Cutoff Wavelength Photodiode on InP Using Lattice-Matched GaInAs—GaAsSb Type-II Quantum Wells”, 2005 International Conference on Indium Phosphide and Related Materials, pp. 148-151

### Patent Literature

PTL 1: Japanese Unexamined Patent Application Publication No. 2003-282927

### SUMMARY OF INVENTION

### Technical Problem

However, the important absorption bands of substances are concentrated in a wavelength range of 1.5 μm to 1.8 μm. Accordingly, when sufficiently high sensitivity in this wavelength range of 1.5 μm to 1.8 μm is achieved and clear images can be obtained, utilization can be promoted.

However, the sensitivity of the above-described type-II InGaAs/GaAsSb MQW sharply drops from a wavelength that is slightly longer than 1.6 μm (refer to FIG. 6). This is because photocurrent is generated by photoelectric conversions due to type-II transition and type-I transition. This results in reduction of contribution of type-I transition from a wavelength of about 1.65 μm. When the sensitivity of a photodiode having the same type-II InGaAs/GaAsSb MQW is measured at a temperature of 200 K to 295 K, the sensitivity also sharply drops from a predetermined wavelength in the wavelength range of 1.5 μm to 1.7 μm (refer to FIG. 6). This is probably caused by the same sensitivity drop factor as described above.

In a photodiode whose upper limit of the absorption wavelength has been slightly increased for optical communications, sufficiently high sensitivity is obtained in the wavelength range of 1.7 μm to 1.8 μm, but the dark current is high.

An object of the present invention is to provide a photodiode that can have sufficiently high sensitivity with stability in a near-infrared wavelength range of 1.5 μm to 1.8 μm and can have a low dark current; and a method for producing the photodiode.

### Solution to Problem

A photodiode according to the present invention contains a III-V compound semiconductor formed on an InP substrate. This photodiode includes a buffer layer positioned on and in contact with the InP substrate, and an absorption layer positioned on and in contact with the buffer layer. This absorption layer includes 50 or more pairs layered such that a first semiconductor layer and a second semiconductor layer constituting a pair are alternately layered, the first semiconductor layer having a bandgap energy of 0.73 eV or less, the second semiconductor layer having a bandgap energy larger than the bandgap energy of the first semiconductor layer, the first semiconductor layer and the second semiconductor layer constitute a strain-compensated quantum well structure, and the first semiconductor layer and the second semiconductor layer each have a thickness of 1 nm or more and 10 nm or less.

As described above, by making the bandgap energy of the first semiconductor layer be 0.73 eV or less, high sensitivity can be obtained in the wavelength range of 1.7 μm to 1.8 μm on the basis of type-I transition within the first semiconductor layer. Here, due to the inverse proportion relationship between bandgap energy and lattice constant, compared with the InP substrate, the first semiconductor layer has a large lattice constant and the second semiconductor layer has a small lattice constant. Accordingly, compressive stress is distributed in the former layer and tensile stress is distributed in the latter layer so that these layers constitute a strain-compensated quantum well structure. When 50 or more pairs of the first semiconductor layer/the second semiconductor layer are provided such that each semiconductor layer has a thickness of 1 nm or more and 10 nm or less, compressive strain and tensile strain due to lattice mismatch are balanced, resulting in macroscopic reduction of the influence of the strains. Accumulation of the strains is thus avoided and, as a result, the crystallinity is enhanced and an increase in the dark current can be suppressed. That is, while high sensitivity is achieved in the wavelength range of about 1.5 μm to about 1.8 μm, the dark current can be suppressed to a low value.

The photodiode may have sensitivity in a range of wavelengths including 1.5 μm and 1.75 μm, and a ratio of a sensitivity at a wavelength of 1.75 μm to a sensitivity at a wavelength of 1.5 μm may be 0.8 or more and 1.2 or less.

As a result, a photodiode having sufficiently high sensitivity in the wavelength range in which the important absorption bands of substances are concentrated can be obtained. Unlike mercury cadmium telluride (MCT, HgCdTe) and the like, which need to be cooled, the photodiode can be generally used at room temperature and hence is easy to use and has a small size. Accordingly, the photodiode can be easily used not only for communications and image capturing at night but also for other wide-ranging applications.

The first semiconductor layer and the second semiconductor layer (1) may constitute a type-II multiple-quantum well structure or (2) may be formed of the same compound semiconductor having different compositions.

As described above, the strain-compensated quantum well structure may be (1) formed as a type-II multiple-quantum well structure or (2) formed of, for example, InGaAs having different compositions. (1) In the former case, light in the wavelength range of 1.7 μm to 1.8 μm can be absorbed not only by type-I transition but also by type-II transition. (2) In the latter case, a type-I multiple-quantum well structure alone is provided and, while high sensitivity is achieved in the wavelength range of about 1.5 μm to about 1.8 μm in which the important absorption bands of substances are concentrated, the dark current can be suppressed to a low value. In this case, since type-II transition does not occur, sensitivity is not obtained in the range of wavelength of more than 1.8 μm. However, for example, the strain-compensated quantum well structure does not contain elements that are difficult to handle such as Sb and hence thin films having good crystallinity can be obtained.

The total thickness of the first semiconductor layers in the absorption layer is preferably 0.5 μm or more.

As a result, in particular, sensitivity at an upper-limit wavelength of about 1.75 μm can be ensured. Absorption at the wavelength of about 1.75 μm is achieved by type-I transition in the bulk of the first semiconductor layer. Accordingly, by making the total thickness be 0.5 μm or more, the sensitivity can be ensured.

The buffer layer preferably has a bandgap energy larger than each of the bandgap energies of the first semiconductor layer and the second semiconductor layer.

As a result, in the substrate-rear-illuminated configuration (, which is necessary for two-dimensionally arrayed pixels), absorption of light by the buffer layer can be suppressed. In addition, since InP (substrate) has a bandgap energy of 1.27 eV, obviously, it does not absorb light in the target wavelength range.

The first semiconductor layer may be formed of InₓGa₁₋ₓAs (0.56≦x≦0.68).

In this case, the first semiconductor layer can be obtained that can absorb light in the wavelength range of 1.7 μm to 1.8 μm with certainty due to type-I transition.

The second semiconductor layer may be formed of In_{y}Ga_{1-y}As (0.38≦y≦0.50).

In this case, the second semiconductor layer having a smaller lattice constant than InP can be combined with the first semiconductor layer having a larger lattice constant than InP to thereby facilitate formation of a strain-compensated quantum well structure. As a result, the whole epitaxial layer even including a window layer can be made to have good crystallinity and the dark current can be reduced. Although this second semiconductor layer can obviously absorb light due to type-I transition, the upper wavelength limit for the light absorption is shorter than 1.7 μm.

The second semiconductor layer may be formed of GaAs_{z}Sb_{1-z}(0.54≦z≦0.66). In this case, the second semiconductor layer having a smaller lattice constant than InP can also be combined with the first semiconductor layer having a larger lattice constant than InP to thereby facilitate formation of a strain-compensated quantum well structure. In this case, the amount of Sb, which is difficult to handle, can be reduced. This is preferable in that the crystallinity of the whole epitaxial layer is enhanced and the dark current is suppressed. In this case, type-II transition can occur; not only light in a long wavelength range of 1.8 μm or more but also light in the target wavelength range of 1.7 μm to 1.8 μm can be absorbed by type-II transition. Specifically, in addition to absorption of light in the wavelength range of 1.7 μm to 1.8 μm due to type-I transition in the first semiconductor layer, light in the wavelength range of 1.7 μm to 1.8 μm can also be absorbed by type-II transition.

An InP window layer is preferably provided in a surface layer of an epitaxial layer including the absorption layer on the InP substrate, and no regrown interface is preferably formed between a bottom surface of the buffer layer and a top surface of the InP window layer.

In this case, the semiconductor epitaxial layer serving as the core of the photodiode can be continuously formed within the same growth chamber (growth chamber in which metal-organic vapor phase epitaxy using only metal-organic sources is performed). Here, the metal-organic vapor phase epitaxy using only metal-organic sources denotes epitaxy in which only metal-organic sources composed of metal-organic compounds are used as the sources for the vapor phase epitaxy, and is referred to as all metal-organic source MOVPE. As a result, contamination with 0, C, or the like at a high concentration in regrown interfaces can be suppressed. As a result, the dark current can be decreased. In addition, since growth can be continuously performed within the same growth chamber, high production efficiency can be achieved.

The buffer layer may contain P.

When the buffer layer contains P, the buffer layer is, for example, an InP buffer layer or an InGaAsP buffer layer. Such a buffer layer can be easily formed as a thin film having good crystallinity. Accordingly, the absorption layer (first and second semiconductor layers) grown on and in contact with this buffer layer can also be formed so as to have good crystallinity. As a result, the dark current can be decreased.

A substrate-rear-illuminated structure for using a rear surface of the InP substrate as an incident surface may be provided.

Here, examples of the structure for receiving light incident on the rear surface of a substrate include (1) an interconnection bump provided for a pixel electrode on the front surface side of the epitaxial layer (a read-out circuit covers the front surface of the epitaxial layer), (2) an antireflection film (AR film) formed on the rear surface side of the substrate, and (3) the form of a two-dimensional array of photodiodes (pixels) serving as base units, which requires receiving of light incident on the rear surface of the substrate (other examples of the structure will be described below).

When the substrate-rear-illuminated structure is provided, photodiodes having two-dimensionally arrayed pixels in which a low dark current is maintained and high sensitivity is ensured can be produced.

Preferably provided are a p-n junction at a front of a region of an impurity introduced by selective diffusion; a diffusive-concentration-distribution-adjusting layer that is formed of a III-V compound semiconductor and is in contact with an upper surface of the absorption layer, the upper surface being on a side opposite to the InP substrate; and a window layer that is on and in contact with the diffusive-concentration-distribution-adjusting layer and contains P. The diffusive-concentration-distribution-adjusting layer preferably has a bandgap energy smaller than a bandgap energy of the window layer.

In this case, when the diffusive-concentration-distribution-adjusting layer has a high electric resistance, for example, a decrease in the sensitivity or delay in image formation is caused. However, by forming the diffusive-concentration-distribution-adjusting layer with a material that has a smaller bandgap energy than the window layer, an increase in the electric resistance can be suppressed. In addition, in pixel formation, while selective diffusion, which allows good crystallinity, is employed, introduction of an impurity into the absorption layer at an excessively high concentration by the selective diffusion can be suppressed to suppress degradation of the crystallinity of the strain-compensated quantum well structure due to the impurity. In this case, the impurity is preferably distributed such that its concentration sharply drops in the diffusive-concentration-distribution-adjusting layer.

A method for producing a photodiode according to the present invention provides a photodiode containing a III-V compound semiconductor formed on an InP substrate. This production method includes a step of forming a buffer layer on the InP substrate; and a step of forming an absorption layer having a multiple-quantum well structure by layering, on the buffer layer, 50 or more pairs in which a first semiconductor layer and a second semiconductor layer constituting a pair are alternately layered, the first semiconductor layer having a bandgap of 0.73 eV or less, the second semiconductor layer having a larger bandgap than the first semiconductor layer, the first and second semiconductor layers each having a thickness of 1 nm or more and 10 nm or less. In the step of forming the absorption layer having a multiple-quantum well structure, the absorption layer is grown by metal-organic vapor phase epitaxy using only metal-organic sources at a growth temperature or substrate temperature of 600° C. or less.

As described above, since the absorption layer has a strain-compensated quantum well structure, whether it has good crystallinity or not is important. In metal-organic vapor phase epitaxy using only metal-organic sources, since a low growth temperature or substrate temperature can be employed, the degree of degradation of crystallinity due to thermal expansion caused by temperature difference during cooling after the growth can be reduced.

The growth temperature or substrate temperature denotes a substrate surface temperature monitored with a pyrometer including an infrared camera and an infrared spectrometer. In the strict sense, this substrate surface temperature is the temperature of the surface of the epitaxial layer formed on the substrate. Although this temperature is referred to as various terms such as substrate temperature, growth temperature, and deposition temperature, all these terms denote the above-described monitored temperature.

A step of forming a III-V compound semiconductor layer on the absorption layer is preferably performed and, from initiation of formation of the absorption layer to end of formation of the III-V compound semiconductor layer, the layers are preferably grown within the same growth chamber by metal-organic vapor phase epitaxy using only metal-organic sources.

In this case, the semiconductor epitaxial layer serving as the core of the photodiode can be continuously formed within the growth chamber by metal-organic vapor phase epitaxy using only metal-organic sources (all metal-organic source MOVPE). As a result, contamination with 0, C, or the like at a high concentration in regrown interfaces can be suppressed. As a result, the dark current can be decreased. In addition, since growth can be continuously performed within the same growth chamber, high production efficiency can be achieved.

### Advantageous Effects of Invention

A photodiode or the like according to the present invention can have sufficiently high sensitivity in a near-infrared wavelength range of 1.5 μm to 1.8 μm with stability and can have a low dark current.

### BRIEF DESCRIPTION OF DRAWINGS

FIG. 1 illustrates a photodiode according to a first embodiment of the present invention. An absorption layer 3 has a multiple-quantum well structure formed by layering 200 pairs of an In_{0.59}Ga_{0.41}As 3a and a GaAs_{0.57}Sb_{0.43} 3b. In the quantum well, the In_{0.59}Ga_{0.41}As 3a and the GaAs_{0.57}Sb_{0.43} 3b each have a thickness of 5 nm. At interfaces 16 and 17 of a photodiode 10, oxygen and carbon concentrations are each less than 1×10¹⁷ cm⁻³.

FIG. 2 illustrates the wavelength dependency of the sensitivity of the photodiode in FIG. 1.

FIG. 3 illustrates the piping system and the like of a deposition apparatus employing metal-organic vapor phase epitaxy using only metal-organic sources.

FIG. 4 is a flow chart of a method for producing the photodiode illustrated in FIG. 1.

FIG. 5 illustrates a photodiode serving as a reference example. An absorption layer 103 has a multiple-quantum well structure formed by layering 200 pairs of an In_{0.53}Ga_{0.47}As 103a and a GaAs_{0.51}Sb_{0.49} 103b. In the quantum well, the In_{0.53}Ga_{0.47}As and the GaAs_{0.51}Sb_{0.49} each have a thickness of 5 nm.

FIG. 6 illustrates the wavelength dependency of the sensitivity of the photodiode in FIG. 5.

FIG. 7 illustrates a photodiode according to a second embodiment of the present invention. An absorption layer 3 has a multiple-quantum well structure formed by layering 200 pairs of an In_{0.59}Ga_{0.41}As 3a and an In_{0.47}Ga_{0.53}As 3c. In the quantum well, the In_{0.59}Ga_{0.41}As 3a and the In_{0.47}Ga_{0.53}As 3c each have a thickness of 5 nm. At interfaces 16 and 17 of a photodiode 10, oxygen and carbon concentrations are each less than 1×10¹⁷ cm⁻³.

FIG. 8 illustrates the wavelength dependency of the sensitivity of the photodiode in FIG. 7.

FIG. 9 is a flow chart of a method for producing the photodiode illustrated in FIG. 7.

### REFERENCE SIGNS LIST

1 InP substrate; 2 InP buffer layer; 3 MQW absorption layer; 3a In_{0.59}Ga_{0.41}As (first semiconductor layer); 3b GaAs_{0.57}Sb_{0.43} (second semiconductor layer); 3c In_{0.47}Ga_{0.53}As (second semiconductor layer); 4 InGaAs layer (diffusive-concentration-distribution-adjusting layer); 5 InP window layer; 6 p-type region; 10 photodiode; 11 p-electrode (pixel electrode); 12 ground electrode (n-electrode); 16 interface between MQW and InGaAs layer; 17 interface between InGaAs layer and InP window layer; 35 AR (antireflection) film; 36 selective diffusion mask pattern; 60 deposition apparatus employing metal-organic vapor phase epitaxy using only metal-organic sources; 61 infrared thermometer; 63 reaction chamber; 65 quartz tube; 66 substrate table; 66h heater; 69 window of reaction chamber

### DESCRIPTION OF EMBODIMENTS

### First Embodiment

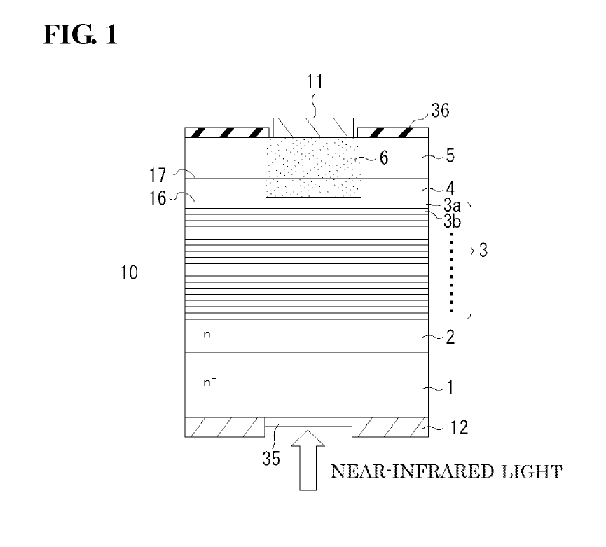

FIG. 1 is a sectional view of a photodiode 10 according to a first embodiment of the present invention. FIG. 1 indicates that the photodiode 10 has, on an InP substrate 1, a III-V compound semiconductor layered structure having the following configuration. (InP substrate 1/InP buffer layer 2/absorption layer 3 having multiple-quantum well structure of In_{0.59}Ga_{0.41}As (first semiconductor layer) 3a and GaAs_{0.57}Sb_{0.43} (second semiconductor layer) 3b/InGaAs diffusive-concentration-distribution-adjusting layer 4/InP window layer 5)

A p-type region 6 extends from the InP window layer 5 to a position near the absorption layer 3 having a multiple-quantum well structure. This p-type region 6 is formed by selective diffusion of Zn, which is a p-type impurity, through the openings of a SiN film serving as a selective diffusion mask pattern 36. This diffusion introduction into a region delimited in plan inside the periphery of the photodiode 10 to form an absorption portion inside the periphery is achieved by diffusion through the SiN film serving as the selective diffusion mask pattern 36.

A p-electrode 11 formed of AuZn is disposed so as to be in ohmic contact with the p-type region 6; and an n-electrode 12 formed of AuGeNi is disposed so as to be in ohmic contact with the rear surface of the InP substrate 1. In this case, the InP substrate 1 is doped with an n-type impurity to ensure a predetermined level of conductivity.

Light is incident on the rear surface of the InP substrate 1. In order to suppress reflection of incident light, an AR (antireflection) film 35 formed of SiON or the like covers the rear surface of the InP substrate 1. This AR film 35 disposed on the rear surface of the InP substrate 1 can be regarded as a structure for receiving light incident on the rear surface of the substrate. In addition, the pixel electrode (p-electrode) 11, which is disposed not in the periphery but in an area closer to the center or in the central area on the top surface of the semiconductor layered body, indicates that light is not incident on the top surface of the semiconductor layered body and can be regarded as a structure for receiving light incident on the rear surface of the semiconductor substrate. Furthermore, a structure (not shown) in which an interconnection bump for connection with a read-out electrode of a read-out circuit is disposed for the pixel electrode can also be regarded as a structure for receiving light incident on the rear surface of the semiconductor substrate. This is because the read-out circuit covers the entirety of the pixel-side surface. Another structure (also not shown) in which both of a ground electrode and a pixel electrode extend on the epitaxial-layer front-surface side is also definitely a structure for receiving light incident on the rear surface of the substrate. These exemplified structures are not given by way of limitation. A substrate-rear-illuminated photodiode necessarily has a structure for receiving light incident on the rear surface of the semiconductor substrate.

The two-dimensional array of pixels P itself employs a flip-flop connection system used for connection with a read-out circuit and hence requires that light is incident on the rear surface of the substrate and is another structure for receiving light incident on the rear surface of the substrate.

A p-n junction is formed at a position corresponding to the boundary front of the p-type region 6. By applying a reverse bias voltage between the p-electrode 11 and the n-electrode 12, in the absorption layer 3, a depletion layer is formed in a larger area on a side in which the concentration of the n-type impurity is lower (n-type impurity background). The background impurity concentration in the absorption layer 3 having a multiple-quantum well structure is, in terms of n-type impurity concentration (carrier concentration), about 5×10¹⁵ cm⁻³ or less. The position of the p-n junction is determined from the point of intersection of the background impurity concentration (n-type carrier concentration) and the concentration profile of p-type impurity Zn in the absorption layer 3 having a multiple-quantum well structure.

In the diffusive-concentration-distribution-adjusting layer 4, the concentration of the p-type impurity selectively diffused through the surface of the InP window layer 5 sharply drops from the high-concentration region on the InP-window-layer side to the absorption-layer side. Accordingly, in the absorption layer 3, an impurity concentration, that is, a Zn concentration of 5×10¹⁶ cm⁻³ or less can be easily achieved.

A photodiode 10 according to the present invention is intended to have sensitivity from the near-infrared range to the longer wavelength range. Accordingly, the window layer is preferably formed of a material having a bandgap energy larger than the bandgap energy of the absorption layer 3. For this reason, the window layer is generally formed of InP, which is a material that has a larger bandgap energy than the absorption layer and is highly lattice-matched. Alternatively, InAlAs, which has substantially the same bandgap energy as InP, may be used.

### (Points in First Embodiment)

Features in the present embodiment lie in the following points.

(1) The first semiconductor layer 3a in the absorption layer 3 is formed of In_{0.59}Ga_{0.41}As in which the In composition is much higher than 0.53 allowing lattice-matching to InP. As a result, a bandgap energy of 0.73 eV or less is achieved. Accordingly, type-I transition in the first semiconductor layer 3a results in an increase in the sensitivity in the wavelength range of 1.7 μm to 1.8

Compared with the composition In_{0.53}Ga_{0.47}As lattice-matched to InP, In_{0.59}Ga_{0.41}As has a very high In composition and hence has a larger lattice constant than InP. Accordingly, compressive stress is distributed in the first semiconductor layer 3a.

(2) The second semiconductor layer 3b is formed of GaAs_{0.57}Sb_{0.43} so that the lattice constant of the second semiconductor layer 3b can be made smaller than that of InP. The composition lattice-matched to InP is GaAs_{0.51}Sb_{0.49}. Compared with this composition, the As composition z is high and the Sb composition (1−z) is very low. As a result, combination of the second semiconductor layer 3b with the first semiconductor layer 3a can provide a strain-compensated quantum well structure in which compressive stress is distributed in the first semiconductor layer 3a and tensile stress is distributed in the second semiconductor layer 3b.

As a result, a low-strain state, that is, a state in which the lattice defect density is low can be achieved and a low dark current can be achieved.

(3) The In_{0.59}Ga_{0.41}As (first semiconductor layer) 3a and the GaAs_{0.57}Sb_{0.43} (second semiconductor layer) 3b constitute a type-II multiple-quantum well structure. A multiple-quantum well structure in which In_{0.53}Ga_{0.47}As and GaAs_{0.51}Sb_{0.49} are lattice-matched has sensitivity in the wavelength range of 2 μm or more due to type-II transition. The energy difference in this type-II transition is smaller than that corresponding to 1.7 μm to 1.8 μm. However, light corresponding to 1.7 μm to 1.8 μm can be obviously absorbed in the type-II transition. As a result, the sensitivity in the wavelength range of 1.5 μm to 1.8 μm can also be enhanced by the type-II transition.

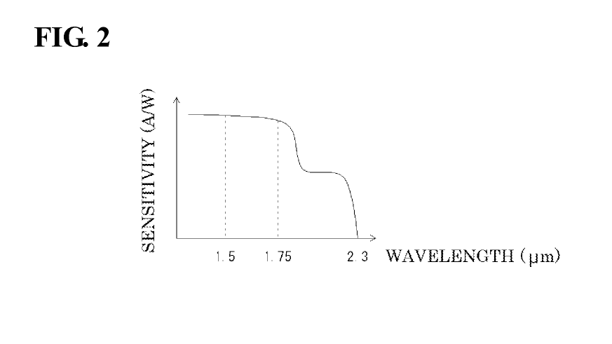

FIG. 2 illustrates the wavelength dependency of the sensitivity of the photodiode 10 illustrated in FIG. 1. Because of (1) to (3) above, the sensitivity in the wavelength range of 1.5 μm to 1.75 μm substantially forms a flat line at a high level continuously from the shorter-wavelength sensitivity. In the present embodiment, (In_{0.59}Ga_{0.41}As/GaAs_{0.57}Sb_{0.43}) in which the type-II transition occurs is used and hence the upper-limit wavelength of the absorption range is about 2.3 μm.

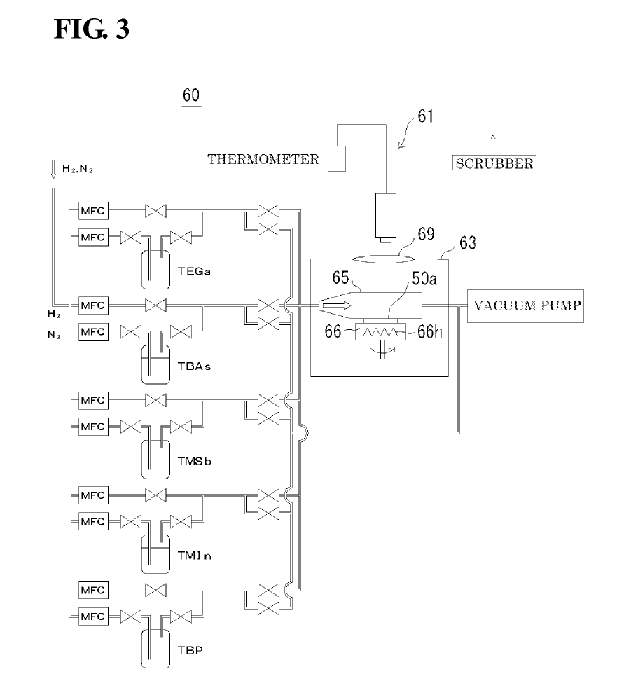

FIG. 3 illustrates the piping system and the like of a deposition apparatus 60 employing metal-organic vapor phase epitaxy using only metal-organic sources. A quartz tube 65 is disposed in a reaction chamber (chamber) 63. Source gases are introduced into the quartz tube 65. In the quartz tube 65, a substrate table 66 is rotatably and hermetically disposed. The substrate table 66 is equipped with a heater 66h for heating a substrate. The surface temperature of a wafer 50a during deposition is monitored with an infrared thermometer 61 through a window 69 provided in the ceiling portion of the reaction chamber 63. This monitored temperature is referred to as, for example, the growth temperature, the deposition temperature, or the substrate temperature. Regarding formation of an MQW at a substrate temperature of 600° C. or less in a production method according to the present invention, this temperature of 600° C. or less is measured in the temperature monitoring. Forced evacuation of the quartz tube 65 is performed with a vacuum pump.

Source gases are supplied through pipes connected to the quartz tube 65. The metal-organic vapor phase epitaxy using only metal-organic sources has a feature of supplying all the source gases in the form of metal-organic gases. Although FIG. 3 does not describe source gases of, for example, impurities, impurities are also introduced in the form of metal-organic gases. The metal-organic source gases are contained in constant temperature baths and kept at constant temperatures. The carrier gases used are hydrogen (H₂) and nitrogen (N₂). The metal-organic gases are carried with the carrier gases and sucked with the vacuum pump to thereby be introduced into the quartz tube 65. The flow rates of the carrier gases are accurately controlled with mass-flow controllers (MFCs). A large number of mass-flow controllers, electromagnetic valves, and the like are automatically controlled with microcomputers.

A method for forming a semiconductor layered structure including the absorption layer 3 on the InP substrate 1 will be described. On a S-doped n-type InP substrate 1, an n-type InP buffer layer 2 is epitaxially grown so as to have a thickness of 150 nm. The n-type doping is preferably performed with tetraethylsilane (TeESi). At this time, source gases used are trimethylindium (TMIn) and tertiarybutylphosphine (TBP). In the growth of the InP buffer layer 2, PH₃ (phosphine), which is an inorganic material, may be used. Even when the InP buffer layer 2 is grown at a growth temperature of about 600° C. or about 600° C. or less, the crystallinity of the underlying InP substrate is not degraded by heating at about 600° C. However, in the formation of the InP window layer 5, an MQW including GaAs_{0.57}Sb_{0.43} is formed thereunder and hence the substrate temperature needs to be strictly kept within the temperature range of, for example, 400° C. or more and 600° C. or less. This is because heating at a temperature more than 600° C. thermally damages GaAs_{0.57}Sb_{0.43}, resulting in considerable degradation of the crystallinity; and, when the InP window layer is formed at a temperature less than 400° C., the decomposition efficiency of source gases is considerably decreased and hence the impurity concentration in the InP layer is increased and an InP window layer 5 having high quality is not obtained.

The buffer layer 2 may be constituted by an InP layer alone. However, in a predetermined case, on this InP buffer layer, an n-doped In_{0.53}Ga_{0.47}As layer may be grown so as to have a thickness of 0.15 μm (150 nm). This In_{0.53}Ga_{0.47}As layer is included in the buffer layer 2 in FIG. 1.

Subsequently, the type-II MQW absorption layer 3 in which In_{0.59}Ga_{0.41}As 3a/GaAs_{0.57}Sb_{0.43} 3b serve as a pair of the quantum well is formed. In the quantum well, the In_{0.59}Ga_{0.41}As 3a and the GaAs_{0.57}Sb_{0.43} 3b each have a film thickness of 1 nm or more and 10 nm or less. In FIG. 1, 200 pairs of the quantum well are layered to form the MQW absorption layer 3. The GaAs_{0.57}Sb_{0.43} 3b is formed with triethylgallium (TEGa), tertiarybutylarsine (TBAs), and trimethylantimony (TMSb). The In_{0.59}Ga_{0.41}As 3a may be formed with TEGa, TMIn, and TBAs. All these source gases are metal-organic gases and the compounds have high molecular weights. Accordingly, the gases are completely decomposed at a relatively low temperature of 400° C. or more and 600° C. or less, contributing to crystal growth. As a result, a temperature difference between the deposition temperature and room temperature can be made small. Thus, strain due to differences in thermal expansion of materials in the photodiode 10 can be reduced and the lattice defect density can be suppressed to a small value. This is advantageous in suppression of dark current.

The Ga (gallium) source may be TEGa (triethylgallium) or trimethylgallium (TMGa). The In (indium) source may be TMIn (trimethylindium) or triethylindium (TEIn). The As (arsenic) source may be TBAs (tertiarybutylarsine) or trimethylarsenic (TMAs). The Sb (antimony) source may be TMSb (trimethylantimony), triethylantimony (TESb), triisopropylantimony (TIPSb), or trisdimethylaminoantimony (TDMASb). By using such sources, a semiconductor element whose MQW has a low impurity concentration and excellent crystallinity can be obtained. As a result, when this element is used for, for example, a photodiode, this photodiode can have a low dark current and high sensitivity. In addition, use of this photodiode allows capture of clear images even from weak light.

Hereinafter, the flow of source gases in the formation of the multiple-quantum well structure 3 by metal-organic vapor phase epitaxy using only metal-organic sources will be described. The source gases are carried through pipes, introduced into the quartz tube 65, and discharged. Any number of source gases may be supplied to the quartz tube 65 by increasing the number of pipes. For example, even more than ten source gases can be controlled by opening/closing of electromagnetic valves.

The flow rates of the source gases are controlled with mass-flow controllers (MFCs) illustrated in FIG. 3 and introduction of the source gases into the quartz tube 65 is turned on/off by opening/closing of electromagnetic valves. The quartz tube 65 is forcibly evacuated with the vacuum pump. The source gases do not stagnate in anywhere and the source gases smoothly automatically flow. Accordingly, switching between compositions during the formation of the pair constituting the quantum well is quickly achieved.

As illustrated in FIG. 3, since the substrate table 66 is rotated, the temperature distribution of source gases does not have orientation relating to source-gas supply side or source-gas discharge side. In addition, since the wafer 50a revolves on the substrate table 66, the source-gas flow in a region near the surface of the wafer 50a is in a turbulent state; and, even source gases in the region near the surface of the wafer 50a, except for source gases in contact with the wafer 50a, have a high velocity component in the flow direction from the supply side to the discharge side. Accordingly, most of heat flowing from the substrate table 66, through the wafer 50a, to the source gases is continuously discharged together with exhaust gas. Thus, a high temperature gradient or a large temperature gap is generated in the vertical direction from the wafer 50a, through its surface, to the source-gas space.

In an embodiment of the present invention, the substrate is heated to a substrate temperature of 400° C. or more and 600° C. or less, which is a low-temperature range. When metal-organic vapor phase epitaxy using only metal-organic sources is employed at a substrate surface temperature in such a low-temperature range with sources such as TBAs, the sources are efficiently decomposed. Accordingly, source gases flowing in a region very close to the wafer 50a and contributing to growth of a multiple-quantum well structure are limited to those having been efficiently decomposed into forms necessary for the growth.

The surface temperature of the wafer 50a is monitored. From the wafer surface to a position slightly into the source-gas space, as described above, there is a sharp drop in the temperature or a large temperature gap. Accordingly, in the case of a source gas having a decomposition temperature of T1° C., the substrate surface temperature is set to (T1+α) where α is determined in view of, for example, variations in the temperature distribution. In a state where a sharp and large temperature drop or temperature gap is present from the surface of the wafer 50a to the source-gas space, when metal-organic molecules having a large size flow over the wafer surface, compound molecules that decompose to contribute to crystal growth are probably limited to molecules in contact with the surface and molecules located within a layer-thickness range extending for a length of several metal-organic molecules from the surface. Accordingly, metal-organic molecules in contact with the wafer surface and molecules located within a layer-thickness range extending for a length of several metal-organic molecules from the wafer surface probably mainly contribute to crystal growth; and metal-organic molecules located on the outer side are probably discharged, without substantial decomposition, from the quartz tube 65. After metal-organic molecules in a region near the surface of the wafer 50a are decomposed to contribute to crystal growth, metal-organic molecules located on the outer side fill in the region.

Conversely, by setting the wafer surface temperature to be slightly higher than the decomposition temperature of metal-organic molecules, metal-organic molecules that participate in crystal growth can be limited to those located in a thin source-gas layer over the surface of the wafer 50a.

From what is described above, when source gases are selected with electromagnetic valves so as to correspond to the chemical compositions of the pair and introduced under forcible evacuation with a vacuum pump, after growth of a crystal having an old chemical composition due to slight inertia, a crystal having a new chemical composition can be grown without being influenced by the old source gases. As a result, an abrupt composition change can be achieved at the heterointerface. This means that the old source gases do not substantially remain in the quartz tube 65. This is because source gases flowing in a region very close to the wafer 50a and contributing to growth of a multiple-quantum well structure are limited to those having been efficiently decomposed into forms necessary for the growth. Specifically, after one layer of the quantum well is formed, source gases for forming the other layer are introduced by opening/closing of electromagnetic valves under forcible evacuation with a vacuum pump; at this time, there are metal-organic molecules participating in the crystal growth due to slight inertia, but most of additional molecules for the one layer are discharged and no longer present. The closer the wafer surface temperature is to the decomposition temperature of metal-organic molecules, the narrower the range (range from the wafer surface) in which metal-organic molecules located therein participate in crystal growth.

When the multiple-quantum well structure is formed by growth in a temperature range of more than 600° C., phase separation occurs in the GaAsSb layers of the multiple-quantum well structure. Accordingly, the crystal growth surface being clean and having excellent flatness in the multiple-quantum well structure and the multiple-quantum well structure excellent in terms of periodicity and crystallinity cannot be obtained. For this reason, the growth temperature is set in a temperature range of 400° C. or more and 600° C. or less; and, it is important that the deposition is performed by all metal-organic source MOVPE and all the source gases are selected from metal-organic gases having high decomposition efficiency.

### <Method for Producing Photodiode>

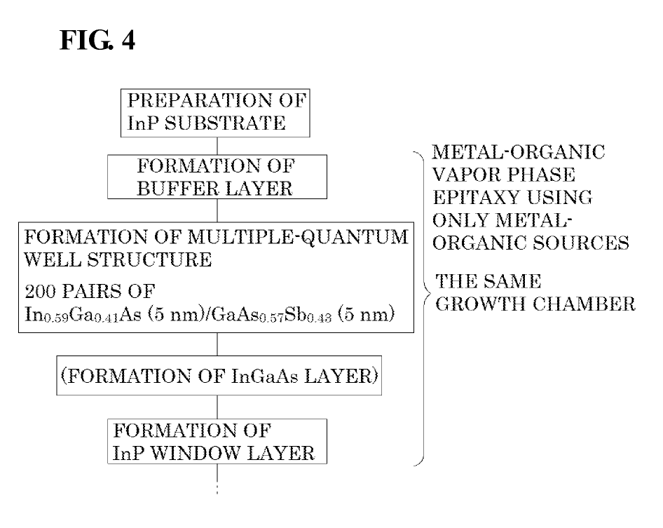

FIG. 4 is a flow chart of a method for producing a photodiode. In the photodiode 10 illustrated in FIG. 1, on the type-II MQW absorption layer 3, the In_{0.53}Ga_{0.47}As diffusive-concentration-distribution-adjusting layer 4 that is lattice-matched to InP is positioned; and, on the In_{0.53}Ga_{0.47}As diffusive-concentration-distribution-adjusting layer 4, the InP window layer 5 is positioned. The p-type region 6 is formed by selective diffusion of Zn, which is a p-type impurity, through the openings of the selective diffusion mask pattern 36 formed on the surface of the InP window layer 5.

At the front of the p-type region 6, a p-n junction or a p-i junction is formed. To this p-n junction or p-i junction, a reverse bias voltage is applied to form a depletion layer; charges due to photoelectric conversion are captured so that the brightness of the pixel matches the charge amount. The p-type region 6 or a p-n junction or a p-i junction is a main portion constituting the pixel. The p-electrode 11 in ohmic contact with the p-type region 6 is a pixel electrode. The charges are read out for each pixel between the p-electrode 11 and the n-electrode 12 that is at ground potential.

The selective diffusion mask pattern 36 is left without being removed around the p-type region 6 and on the surface of the InP window layer. Furthermore, a passivation layer (not shown) composed of SiON or the like is formed thereon. The selective diffusion mask pattern 36 is left without being removed because, when the p-type region 6 is formed and the selective diffusion mask pattern 36 is then removed to expose the p-type region 6 in the air, a surface level is formed at the boundary between the surface of the contact layer and the p-type region, resulting in an increase in the dark current.

It is a point that, from the end of the above-described formation of the MQW to the formation of the InP window layer 5, growth by metal-organic vapor phase epitaxy using only metal-organic sources is continued within the same growth chamber or quartz tube 65. That is, prior to the formation of the InP window layer 5, the wafer 50a is not taken out of the growth chamber and the InP window layer 5 is not formed by another deposition process; accordingly, regrown interfaces are not formed, which is a point. In other words, the InGaAs diffusive-concentration-distribution-adjusting layer 4 and the InP window layer 5 are continuously formed within the quartz tube 65 and hence interfaces 16 and 17 are not regrown interfaces.

Accordingly, in the interfaces 16 and 17 of the photodiode 10 in FIG. 1, oxygen and carbon concentrations are each less than 1×10¹⁷ cm⁻³, which is less than the predetermined level. In particular, leakage current does not occur in the cross line between the p-type region 6 and the interface 17. In addition, in the interface 16, the lattice defect density is suppressed to a low value.

In the present embodiment, on the MQW absorption layer 3, for example, the non-doped In_{0.53}Ga_{0.47}As diffusive-concentration-distribution-adjusting layer 4 having a thickness of 1.0 μm is formed. After the formation of the InP window layer 5, when Zn, which is a p-type impurity, is introduced by a selective diffusion method from the InP window layer 5 so as to reach the MQW absorption layer 3, diffusion of Zn at a high concentration into the MQW results in degradation of the crystallinity. The In_{0.53}Ga_{0.47}As diffusive-concentration-distribution-adjusting layer 4 is formed to adjust the diffusion of Zn. The In_{0.53}Ga_{0.47}As diffusive-concentration-distribution-adjusting layer 4 may be formed as described above, or may be omitted.

As a result of the selective diffusion, the p-type region 6 is formed and a p-n junction or a p-i junction is formed at the front of the p-type region 6. Even when the In_{0.53}Ga_{0.47}As diffusive-concentration-distribution-adjusting layer 4 is inserted and it is a non-doped layer, In_{0.53}Ga_{0.47}As has a narrow bandgap and hence the photodiode can be made to have a low electric resistance. By decreasing the electric resistance, the responsivity can be enhanced and moving images having high image quality can be obtained.

While the wafer 50a is continuously left in the same quartz tube 65, on the In_{0.53}Ga_{0.47}As diffusive-concentration-distribution-adjusting layer 4, the undoped InP window layer 5 is preferably epitaxially grown by metal-organic vapor phase epitaxy using only metal-organic sources so as to have a thickness of, for example, 0.8 μm. As described above, the source gases are trimethylindium (TMIn) and tertiarybutylphosphine (TBP). By using these source gases, the growth temperature for the InP window layer 5 can be made to be 400° C. or more and 600° C. or less, further 550° C. or less. As a result, GaAsSb of the MQW underlying the InP window layer 5 is not thermally damaged and the crystallinity of the MQW is not degraded. In the formation of the InP window layer 5, since the MQW containing GaAsSb is formed thereunder, the substrate temperature needs to be strictly maintained in the range of, for example, 400° C. or more and 600° C. or less. This is because heating to more than 600° C. thermally damages GaAs_{0.57}Sb_{0.43} and the crystallinity is considerably degraded; and, when an InP window layer is formed at a temperature less than 400° C., the decomposition efficiency of source gases becomes very low and hence the impurity concentration in the InP window layer 5 becomes high and the InP window layer 5 having high quality is not obtained.

As described above, an MQW has been required to be formed by molecular beam epitaxy (MBE). However, growth of an InP window layer by MBE requires use of solid phosphorus source and hence has problems in terms of safety and the like; in addition, the production efficiency needs to be enhanced.

Before the present invention has been accomplished, the interface between the In_{0.53}Ga_{0.47}As diffusive-concentration-distribution-adjusting layer and the InP window layer was a regrown interface having been exposed to the air. Such a regrown interface can be identified through secondary ion mass spectrometry in which it satisfies at least one of an oxygen concentration of 1×10¹⁷ cm⁻³ or more and a carbon concentration of 1×10¹⁷ cm⁻³ or more. The regrown interface forms a cross line through the p-type region; leakage current occurs in the cross line and image quality is considerably degraded.

Alternatively, for example, in the case of growth of an InP contact layer by MOVPE (metal-organic vapor phase epitaxy not using only metal-organic sources) simply employing phosphine (PH₃) as the phosphorus source, the decomposition temperature of phosphine is high and the underlying GaAs_{0.57}Sb_{0.43} is thermally damaged, resulting in degradation of the crystallinity of the MQW.

According to the above-described production method, only metal-organic gases are used as source gases to decrease the growth temperature; and growth is continuously performed within the same growth chamber or quartz tube 65 until the end of formation of the InP window layer 5 and hence regrown interfaces are not formed. As a result, a large number of photodiodes having a low leakage current, high crystallinity, and sensitivity in the wavelength range of 1.5 μm to 1.8 μm can be efficiently produced.

### Reference Example

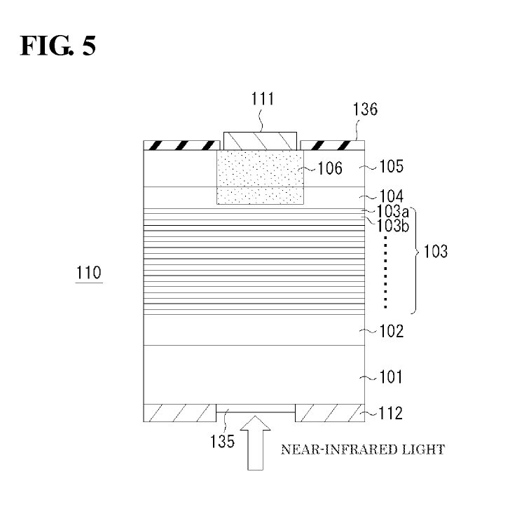

FIG. 5 is a sectional view of a photodiode 110 serving as a reference example. The layered structure is similar to that of the photodiode 10 in FIG. 1 according to an embodiment of the present invention. Specifically, the photodiode 110 has a layered structure of (InP substrate 101/InP buffer layer 102/absorption layer 103 having multiple-quantum well structure of In_{0.53}Ga_{0.47}As and GaAs_{0.51}Sb_{0.49}/In_{0.53}Ga_{0.47}As diffusive-concentration-distribution-adjusting layer 104/InP window layer 105). The absorption layer 103 is formed by layering 200 pairs of the quantum well. The biggest difference in this reference example is that an In_{0.53}Ga_{0.47}As layer 103a and a GaAs_{0.51}Sb_{0.49} layer 103b that constitute the absorption layer 103 have compositions that are lattice-matched to InP. Existing multiple-quantum well structures have been formed as (In_{0.53}Ga_{0.47}As layer 103a/GaAs_{0.5} Sb_{0.49} layer 103b) having compositions that are lattice-matched to InP. In existing type-II multiple-quantum well structures formed of In_{0.53}Ga_{0.47}As and GaAs_{0.51}Sb_{0.49}, multiple-quantum well structures having compositions that allow lattice-matching as illustrated in FIG. 5 have been employed without exception.

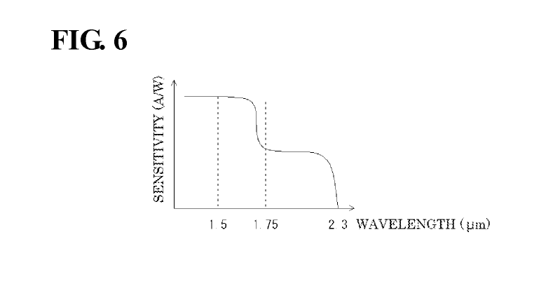

FIG. 6 illustrates the wavelength dependency of the sensitivity of the photodiode 110 illustrated in FIG. 5. The type-II multiple-quantum well structure formed of In_{0.53}Ga_{0.47}As and GaAs_{0.51}Sb_{0.49} is reflected and, as a result, the upper-limit wavelength of the sensitivity is 2.3 μm. However, in the wavelength range of 1.5 μm to 1.75 μm, in which the important absorption bands of substances are concentrated, the sensitivity sharply drops on the long-wavelength side. This causes problems in performing reliable analysis using a plurality of absorption bands that are concentrated in the wavelength range of 1.5 μm to 1.75 μm.

### Second Embodiment

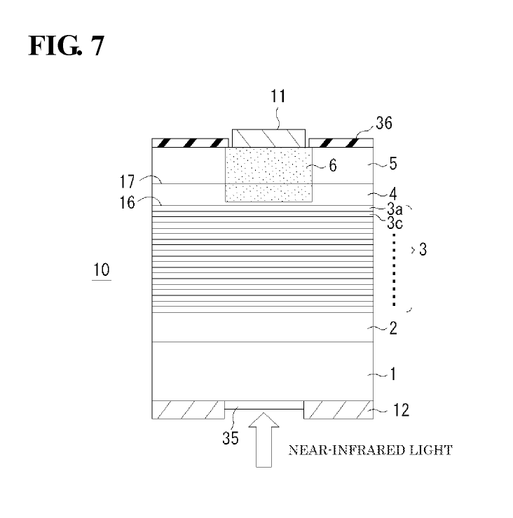

FIG. 7 illustrates a photodiode 10 according to a second embodiment of the present invention.

(InP substrate 1/InP buffer layer 2/absorption layer 3 having layered body of (In_{0.59}Ga_{0.41}As) 3a and (In_{0.47}Ga_{0.53}As) 3c/In_{0.53}Ga_{0.47}As diffusive-concentration-distribution-adjusting layer 4/InP window layer 5)

Zinc (Zn), which is a p-type impurity, is selectively diffused through the InP window layer 5 to form the pixel. The selectively diffused Zn has a distribution in which, in the In_{0.53}Ga_{0.47}As diffusive-concentration-distribution-adjusting layer 4, 1×10¹⁸ cm⁻³ to 1×10¹⁹ cm⁻³ on the InP window layer 5 side sharply drops to 5×10¹⁶ cm⁻³ or less on the absorption layer side.

The above-described layered structure is constituted on the basis of the following concepts.

### 1. In_{0.59}Ga_{0.41}as 3a (First Semiconductor Layer) in Absorption Layer 3

In order to minimize the bandgap to thereby allow absorption of long-wavelength light, the In composition x is made to be 0.59. As a result, the upper-limit wavelength of the absorption range can be increased to about 1800 nm. However, the In_{0.59}Ga_{0.41}As 3a has such a large lattice constant that the In_{0.59}Ga_{0.41}As 3a alone is less likely to be lattice-matched to InP. As a result, the lattice defect density becomes high and the dark current increases. Accordingly, it becomes difficult to detect weak light with sufficiently high resolution.

### 2. In_{0.47}Ga_{0.53}as 3c (Second Semiconductor Layer) in Absorption Layer 3:

(1) In the second semiconductor In_{0.47}Ga_{0.53}As 3c, the In composition y is made 0.12 smaller than the In composition x of the first semiconductor. Since the first semiconductor In_{0.59}Ga_{0.41}As 3a has a large lattice constant, the second semiconductor In_{0.47}Ga_{0.53}As 3c having a small lattice constant is used to achieve the balance in terms of lattice matching.

Specifically, the lattice constant of InP is defined as a₀, the lattice constant of the first semiconductor layer is defined as a₁, and the lattice constant of the second semiconductor layer is defined as a₂. InP has a bandgap energy of 1.27 eV and the first semiconductor layer has a bandgap energy of 0.73 eV or less. Thus, the lattice constant (a₁) of the first semiconductor layer is larger than the lattice constant (a₀) of InP. That is, there is a relation of a₁>a₀.

When the second semiconductor layer is formed of In_{y}Ga_{1-y}As (0.38≦y≦0.50), a₀>a₂ is satisfied; and a₁−a₀ (>0) and a₀−a₂ (>0) become substantially the same positive values.

When the first semiconductor layer 3a and the second semiconductor layer 3c described above are combined, the In_{0.59}Ga_{0.41}As 3a in which compressive strain is distributed and the In_{0.47}Ga_{0.53}As 3c in which tensile strain is distributed constitute a strain-compensated MQW. As a result, in the thickness range of the absorption layer 3, it can be considered that the absorption layer 3 having an average lattice constant between the In_{0.59}Ga_{0.41}As 3a and the In_{0.47}Ga_{0.53}As 3c is disposed. As a result, the diffusive-concentration-distribution-adjusting layer 4 grown on and in contact with the absorption layer 3 and the window layer 5 do not have a high lattice defect density. Thus, the In_{0.53}Ga_{0.47}As diffusive-concentration-distribution-adjusting layer 4/the InP window layer 5 having good surface properties are formed, and the dark current does not become high.

(2) While the first semiconductor In_{0.59}Ga_{0.41}As 3a absorbs light at about the upper-limit wavelength (1800 nm) of the absorption range, the In_{0.47}Ga_{0.53}As 3c absorbs light corresponding to a larger bandgap energy. Obviously, the first semiconductor In_{0.59}Ga_{0.41}As 3a itself absorbs not only long-wavelength light at about the upper-limit wavelength but also light having a shorter wavelength.

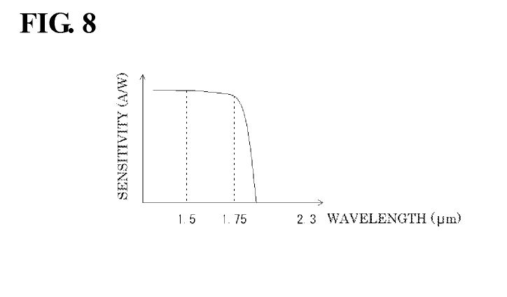

FIG. 8 illustrates the wavelength dependency of the sensitivity of the photodiode 10 illustrated in FIG. 7. Because of (1) and (2) above, the sensitivity in the wavelength range of 1.5 μm to 1.75 μm substantially forms a flat line at a high level continuously from the shorter-wavelength sensitivity. In the present embodiment, the type-II transition does not occur and the upper-limit wavelength of the absorption range is determined with the type-I transition in the first semiconductor In_{0.59}Ga_{0.41}As 3a.

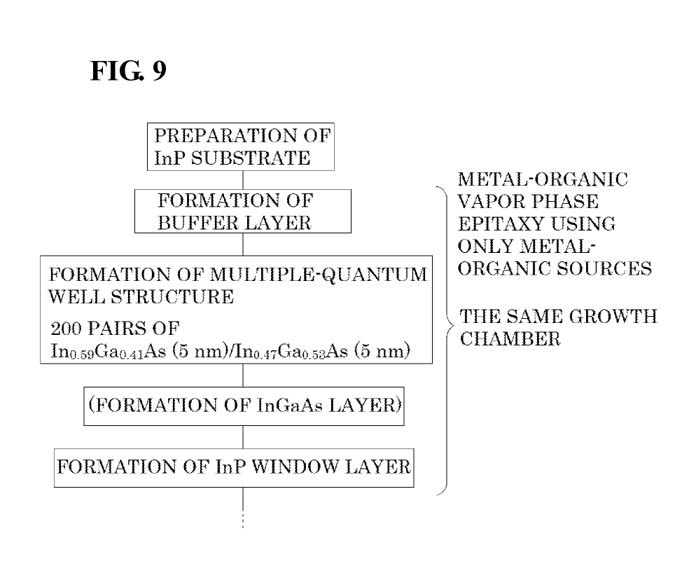

FIG. 9 is a flow chart of a method for producing the photodiode 10 illustrated in FIG. 7. This method is the same as in the first embodiment except that the multiple-quantum well structure is constituted by the In_{0.59}Ga_{0.41}As 3a and the In_{0.47}Ga_{0.53}As 3c.

### EXAMPLES

### Example 1

Photodiodes corresponding to the first embodiment were actually produced and evaluated in terms of sensitivities at wavelengths of 1.5 μm and 1.75 μm and dark current. Eight test samples A1 to A8 described in Table I were used. Of these test samples, test samples A3 to A7 are invention examples and test samples A1, A2, and A8 are comparative examples. In each test sample, the first semiconductor layer 3a was formed of In_{0.59}Ga_{0.41}As and the second semiconductor layer 3b was formed of GaAs_{0.57}Sb_{0.43}. The thickness configurations are as follows.

Invention example A3: (1 nm/1 nm)×250 pairs, absorption-layer thickness: 0.5 μm

Invention example A4: (5 nm/5 nm)×50 pairs, absorption-layer thickness: 0.5 μm

Invention example A5: (5 nm/5 nm)×100 pairs, absorption-layer thickness: 1.0 μm

Invention example A6: (5 nm/5 nm)×200 pairs, absorption-layer thickness: 2.0 μm

Invention example A7: (10 nm/10 nm)×100 pairs, absorption-layer thickness: 2.0 μm

Comparative example A1: (5 nm/5 nm)×40 pairs, absorption-layer thickness: 0.4 μm

Comparative example A2: (0.5 nm/0.5 nm)×500 pairs, absorption-layer thickness: 0.5 μm

Comparative example A8: (20 nm/20 nm)×50 pairs, absorption-layer thickness: 2.0 μm

In the tests, sensitivities (A/W) at wavelengths of 1.5 μm and 1.75 μm and dark current were measured. The sensitivity at each wavelength was measured at room temperature on the basis of a photocurrent generated upon incident of white light on the rear surface of a substrate through a band-pass filter corresponding to the wavelength. The dark current was measured at room temperature on the basis of a current flowing under no light illumination. A dark current of 10 mA/cm² or more was evaluated as Poor; and a dark current of less than 10 mA/cm² was evaluated as Good. Regarding the sensitivities, a case where the ratio of the sensitivity at a wavelength of 1.75 μm to the sensitivity at a wavelength of 1.5 μm was 0.8 or more and these sensitivities were each 0.20 A/W or more was evaluated as Good; and a case where the sensitivity ratio was less than 0.8 was evaluated as Poor. In terms of dark current and sensitivities, test samples that were not evaluated as Poor were evaluated as Good in Overall evaluation; and, in particular, a case where the sensitivities were 1.0 A/W or more was evaluated as Excellent.

TABLE 1

| | Thickness | Thickness | | | | | | | | |
|---|---|---|---|---|---|---|---|---|---|---|
| | of first | of second | | | | | | | | |
| | semiconductor | semiconductor | | Absorption- | Sensitivity | Sensitivity | Sensitivity | Sensitivity | | |
| Test | layer | layer | Number | layer | wavelength | wavelength | wavelength | (1.75 μm)/ | Evaluation | |
| sample | In_{0.59}Ga_{0.41}As | GaAs_{0.57}Sb_{0.43} | of | thickness | 1.5 μm | 1.75 μm | 2.0 μm | sensitivity | of | Overall |
| No. | (nm) | (nm) | pairs | (μm) | (A/W) | (A/W) | (A/W) | (1.5 μm) | dark current | evaluation |
| A1 | 5 | 5 | 40 | 0.4 | 0.20 | 0.15 | 0.1 | 0.75 | Good | Poor |
| A2 | 0.5 | 0.5 | 500 | 0.5 | 0.13 | 0.10 | 0.1 | 0.8 | Poor | Poor |
| A3 | 1 | 1 | 250 | 0.5 | 0.25 | 0.20 | 0.2 | 0.8 | Good | Good |
| A4 | 5 | 5 | 50 | 0.5 | 0.25 | 0.20 | 0.1 | 0.8 | Good | Good |
| A5 | 5 | 5 | 100 | 1.0 | 0.50 | 0.40 | 0.2 | 0.8 | Good | Good |
| A6 | 5 | 5 | 200 | 2.0 | 1.1 | 1.0 | 0.4 | 0.9 | Good | Excellent |
| A7 | 10 | 10 | 100 | 2.0 | 1.1 | 1.0 | 0.2 | 0.9 | Good | Good |
| A8 | 20 | 20 | 50 | 2.0 | 1.1 | 1.0 | 0.1 | 0.9 | Poor | Poor |

As described in Table I, in Invention examples A3 to A7, the sensitivity ratio was 0.8 or more and the evaluation in terms of dark current was also Good. In particular, Invention example A6 was evaluated as being excellent in terms of sensitivities and dark current and evaluated as Excellent in Overall evaluation. In contrast, in Comparative example A1, the sensitivity ratio was poor. In Comparative example A2, the sensitivities were low and the dark current was also high. In Comparative example A8, the sensitivities at wavelengths of 1.5 μm and 1.75 μm were good; however, the dark current was very high.

### Example 2

Photodiodes corresponding to the second embodiment were actually produced and evaluated in terms of sensitivities at wavelengths of 1.5 μm and 1.75 μm and dark current. Eight test samples B1 to B8 described in Table II were used. Of these test samples, test samples B3 to B7 are invention examples and test samples B1, B2, and B8 are comparative examples. In each test sample, the first semiconductor layer 3a was formed of In_{0.59}Ga_{0.41}As and the second semiconductor layer 3c was formed of In_{0.47}Ga_{0.53}As. The thickness configurations are as follows.

Invention example B3: (1 nm/1 nm)×250 pairs, absorption-layer thickness: 0.5 μm

Invention example B4: (5 nm/5 nm)×50 pairs, absorption-layer thickness: 0.5 μm

Invention example B5: (5 nm/5 nm)×100 pairs, absorption-layer thickness: 1.0 μm

Invention example B6: (5 nm/5 nm)×200 pairs, absorption-layer thickness: 2.0 μm

Invention example B7: (10 nm/10 nm)×100 pairs, absorption-layer thickness: 2.0 μm

Comparative example B1: (5 nm/5 nm)×40 pairs, absorption-layer thickness: 0.4 μm

Comparative example B2: (0.5 nm/0.5 nm)×500 pairs, absorption-layer thickness: 0.5 μm

Comparative example B8: (20 nm/20 nm)×50 pairs, absorption-layer thickness: 2.0 μm

In the tests, sensitivities (A/W) at wavelengths of 1.5 μm and 1.75 μm and dark current were measured. A dark current of 10 mA/cm² or more was evaluated as Poor; and a dark current of less than 10 mA/cm² was evaluated as Good. Regarding the sensitivities, a case where the ratio of the sensitivity at a wavelength of 1.75 μm to the sensitivity at a wavelength of 1.5 μm was 0.8 or more and these sensitivities were each 0.20 A/W or more was evaluated as Good; and a case where the sensitivity ratio was less than 0.8 was evaluated as Poor. In terms of dark current and sensitivities, test samples that were not evaluated as Poor were evaluated as Good in Overall evaluation; and, in particular, a case where the sensitivities were 1.0 A/W or more was evaluated as Excellent.

TABLE II

| | Thickness | Thickness | | | | | | | | |
|---|---|---|---|---|---|---|---|---|---|---|
| | of first | of second | | | | | | | | |
| | semiconductor | semiconductor | | Absorption- | Sensitivity | Sensitivity | Sensitivity | Sensitivity | | |
| Test | layer | layer | Number | layer | wavelength | wavelength | wavelength | (1.75 μm)/ | Evaluation | |
| sample | In_{0.59}Ga_{0.41}As | In_{0.47}Ga_{0.53}As | of | thickness | 1.5 μm | 1.75 μm | 2.0 μm | sensitivity | of | Overall |
| No. | (nm) | (nm) | pairs | (μm) | (A/W) | (A/W) | (A/W) | (1.5 μm) | dark current | evaluation |
| B1 | 5 | 5 | 40 | 0.4 | 0.20 | 0.15 | 0 | 0.75 | Good | Poor |
| B2 | 0.5 | 0.5 | 600 | 0.5 | 0.13 | 0.10 | 0 | 0.8 | Poor | Poor |
| B3 | 1 | 1 | 250 | 0.5 | 0.25 | 0.20 | 0 | 0.8 | Good | Good |
| B4 | 5 | 5 | 50 | 0.5 | 0.25 | 0.20 | 0 | 0.8 | Good | Good |
| B5 | 5 | 5 | 100 | 1.0 | 0.50 | 0.40 | 0 | 0.8 | Good | Good |
| B6 | 5 | 5 | 200 | 2.0 | 1.1 | 1.0 | 0 | 0.9 | Good | Excellent |
| B7 | 10 | 10 | 100 | 2.0 | 1.1 | 1.0 | 0 | 0.9 | Good | Good |
| B8 | 20 | 20 | 50 | 2.0 | 1.1 | 1.0 | 0 | 0.9 | Poor | Poor |

As described in Table II, in Invention examples B3 to B7, the sensitivity ratio was 0.8 or more and the evaluation in terms of dark current was also Good. In particular, Invention example B6 was evaluated as being excellent in terms of sensitivities and dark current and evaluated as Excellent in Overall evaluation. In contrast, in Comparative example B1, the sensitivity ratio was poor. In Comparative example B2, the sensitivities were poor and the dark current was also high. In Comparative example B8, the sensitivities at wavelengths of 1.5 μm and 1.75 μm were good; however, the dark current was very high.

Embodiments of the present invention have been described so far. However, embodiments of the present invention disclosed above are given by way of illustration, and the scope of the present invention is not limited to these embodiments. The scope of the present invention is indicated by Claims and embraces all the modifications within the meaning and range of equivalency of the Claims.

### INDUSTRIAL APPLICABILITY

In a photodiode or the like according to the present invention, the sensitivity forms a flat line at a sufficiently high level over a near-infrared wavelength range of 1.5 μm to 1.8 μm and the dark current can be low. Accordingly, clear images can be obtained even under small amounts of light and the photodiode or the like can be suitably applied not only to communications and image capturing at night but also to other wide-ranging applications.

1. A photodiode containing a III-V compound semiconductor formed on an InP substrate, the photodiode comprising:
a buffer layer positioned on and in contact with the InP substrate, and
an absorption layer positioned on and in contact with the buffer layer,
wherein the absorption layer includes 50 or more pairs layered such that a first semiconductor layer and a second semiconductor layer constituting a pair are alternately layered, the first semiconductor layer having a bandgap energy of 0.73 eV or less, the second semiconductor layer having a bandgap energy larger than the bandgap energy of the first semiconductor layer,
the first semiconductor layer and the second semiconductor layer constitute a strain-compensated quantum well structure, and the first semiconductor layer and the second semiconductor layer each have a thickness of 1 nm or more and 10 nm or less.

2. The photodiode according to claim 1, wherein the photodiode has sensitivity in a range of wavelengths including 1.5 μm and 1.75 μm, and a ratio of a sensitivity at a wavelength of 1.75 μm to a sensitivity at a wavelength of 1.5 μm is 0.8 or more and 1.2 or less.

3. The photodiode according to claim 1, wherein the first semiconductor layer and the second semiconductor layer (1) constitute a type-II multiple-quantum well structure or (2) are formed of the same compound semiconductor having different compositions.

4. The photodiode according claim 1, wherein a total thickness of the first semiconductor layers in the absorption layer is 0.5 μm or more.

5. The photodiode according to claim 1, wherein the buffer layer has a bandgap energy larger than each of the bandgap energies of the first semiconductor layer and the second semiconductor layer.

6. The photodiode according to claim 1, wherein the first semiconductor layer is formed of InₓGa₁₋ₓAs (0.56≦x≦0.68).

7. The photodiode according to claim 1, wherein the second semiconductor layer is formed of In_{y}Ga_{1-y}As (0.38≦y≦0.50).

8. The photodiode according to claim 1, wherein the second semiconductor layer is formed of GaAs_{z}Sb_{1-z} (0.54≦z≦0.66).

9. The photodiode according to claim 1, comprising an InP window layer in a surface layer of an epitaxial layer including the absorption layer on the InP substrate, wherein no regrown interface is formed between a bottom surface of the buffer layer and a top surface of the InP window layer.

10. The photodiode according to claim 1, wherein the buffer layer contains P.

11. The photodiode according to claim 1, comprising a substrate-rear-illuminated structure for using a rear surface of the InP substrate as an incident surface.

12. The photodiode according to claim 1, comprising a p-n junction at a front of a region of an impurity introduced by selective diffusion; a diffusive-concentration-distribution-adjusting layer that is formed of a III-V compound semiconductor and is in contact with an upper surface of the absorption layer, the upper surface being on a side opposite to the InP substrate; and a window layer that is on and in contact with the diffusive-concentration-distribution-adjusting layer and contains P, wherein the diffusive-concentration-distribution-adjusting layer has a bandgap energy smaller than a bandgap energy of the window layer.

13. A method for producing a photodiode containing a III-V compound semiconductor formed on an InP substrate, the method comprising:
a step of forming a buffer layer on the InP substrate; and
a step of forming an absorption layer having a multiple-quantum well structure by layering, on the buffer layer, 50 or more pairs in which a first semiconductor layer and a second semiconductor layer constituting a pair are alternately layered, the first semiconductor layer having a bandgap of 0.73 eV or less, the second semiconductor layer having a larger bandgap than the first semiconductor layer, the first and second semiconductor layers each having a thickness of 1 nm or more and 10 nm or less,
wherein, in the step of forming the absorption layer having a multiple-quantum well structure, the absorption layer is grown by metal-organic vapor phase epitaxy using only metal-organic sources at a growth temperature or substrate temperature of 600° C. or less.

14. The method for producing a photodiode according to claim 13, comprising a step of forming a III-V compound semiconductor layer on the absorption layer, wherein, from initiation of formation of the absorption layer to end of formation of the III-V compound semiconductor layer, the layers are grown within the same growth chamber by metal-organic vapor phase epitaxy using only metal-organic sources.
